(19) United States
(12) Patent Application Publication
(10) Pub. No.: US 2021/0057680 A1
(43) Pub. Date: Feb. 25, 2021

(54) DISPLAY DEVICE PRODUCTION METHOD

(71) Applicant: SHARP KABUSHIKI KAISHA, Sakai City, Osaka (JP)

(72) Inventor: KAZUHIKO IWASA, Sakai City, Osaka (JP)

(21) Appl. No.: 17/042,898

(22) PCT Filed: Mar. 30, 2018
(86) PCT No.: PCT/JP2018/013829

§ 371 Date: Sep. 28, 2020

(51) Int. Cl. H01L 51/56; H01L 51/52; H01L 51/00

(52) U.S. Cl. CPC H01L 51/56; H01L 51/0015; H01L 51/5253

(57) ABSTRACT

A manufacturing method of a display device includes inspecting a position and a height of a protrusion present in a formation region of a first flattened layer, selecting the protrusion having a height equal to or greater than a threshold value, and polishing the protrusion to make the height of the protrusion less than the thickness of the first flattened layer.

### TECHNICAL FIELD

The present invention relates to a manufacturing method of a display device.

### BACKGROUND ART

PTL 1 discloses covering, with an organic buffer layer, a foreign matter adhered to an arrangement region for a light-emitting element in a display device or the like to flatten the arrangement region before the light-emitting element is finally sealed with an inorganic sealing layer. Additionally, PTL 2 discloses covering a foreign matter with a lower inorganic sealing layer, polishing and flattening the entire surface of the lower inorganic sealing layer, and then forming an upper inorganic sealing layer on the lower inorganic sealing layer.

### CITATION LIST

### Patent Literature

PTL 1: Japanese Patent Application Publication No. 2015-56335 A (published on Mar. 23, 2015)

PTL 2: Japanese Patent Application Publication No. 2014-093195 A (published on May 19, 2014)

### SUMMARY OF INVENTION

### Technical Problem

However, PTL 1 does not take into consideration any foreign matter having a height equal to or greater than the thickness of the organic buffer layer. In a case where a foreign matter having a height equal to or greater than the thickness of the organic buffer layer is present, the coverage of the inorganic sealing layer formed on the organic buffer layer is negatively affected, leading to poor sealing. Since the light-emitting element is susceptible to moisture, oxygen, and the like, in a case where the light-emitting element comes into contact with a trace amount of moisture or oxygen, properties of the light-emitting element deteriorate, leading to problems such as reduced reliability of an apparatus finally obtained.

In addition, in the method of PTL 2, the entire lower inorganic sealing layer is polished and flattened, and thus there is a problem in that defects such as cracks may occur in the lower inorganic sealing layer or a surface of a structure beneath the lower inorganic sealing layer may be polished. In addition, in a case that the foreign matter is completely removed by polishing, the layer beneath the foreign matter may be damaged.

### Solution to Problem

To solve the above problem, a manufacturing method of a display device according to an aspect of this application is a manufacturing method of a display device including a light-emitting element layer including a plurality of light-emitting elements and a sealing film covering the light-emitting element layer, the sealing film including a first flattened layer and a first inorganic sealing layer provided on the first flattened layer, the manufacturing method including a light-emitting element layer forming step of forming the light-emitting element layer, an inspection step of inspecting, after the light-emitting element layer forming step, a position and a height of a protrusion present in a formation region of the first flattened layer, including at least a foreign matter, and protruding upward from a plane at a periphery of the foreign matter, a selection step of selecting the protrusion having a height equal to or greater than a threshold value, a polishing step of polishing a portion of the protrusion having a height equal to or greater than the threshold value to make the height of the protrusion less than a thickness of the first flattened layer, a first flattened layer forming step of forming the first flattened layer to cover the protrusion polished in the polishing step, and a first inorganic sealing layer forming step of forming the first inorganic sealing layer on the first flattened layer.

### Advantageous Effects of Invention

According to one aspect of the present invention, the foreign matter having a height equal to or greater than the threshold value is selected, only a part of the protrusion including at least the foreign matter is polished to a height at which the part can be covered with the first flattened layer, and not the entire protrusion is polished. In other words, according to an aspect of the present invention, not the entire surface of the sealing film is polished and not all of the foreign matter is polished or removed. Thus, a manufacturing method of a display device can be provided that can suppress poor sealing before forming the first inorganic sealing layer and that can manufacture a highly reliable display device.

### BRIEF DESCRIPTION OF DRAWINGS

FIG. 1 is a flowchart illustrating an example of a manufacturing method of a display device according to a first embodiment.

FIG. 2 is a cross-sectional view illustrating a configuration of a display region of the display device according to the first embodiment.

FIG. 3 is a plan view illustrating a general configuration of the display device according to the first embodiment.

FIG. 4 is a flowchart illustrating an example of a sealing film forming step according to the first embodiment.

FIGS. 5(a) to 5(f) are cross-sectional views illustrating the sealing film forming step according to the first embodiment in order of relevant steps.

FIG. 6 is a cross-sectional view illustrating a configuration of a display region of a display device according to a second embodiment.

FIG. 7 is a flowchart illustrating an example of a sealing film forming step according to the second embodiment.

FIGS. 8(a) to 8(f) are cross-sectional views illustrating the sealing film forming step according to the second embodiment in order of relevant steps.

FIG. 9 is a flowchart illustrating an example of a sealing film forming step according to a third embodiment.

FIGS. 10(a) to 10(g) are cross-sectional views illustrating a part of the sealing film forming step according to the third embodiment in order of relevant steps.

FIG. 11 is a flowchart illustrating an example of the steps from a light-emitting element layer forming step through a sealing film forming step according to a fourth embodiment.

FIG. 12 is a flowchart illustrating an example of a sealing film forming step according to the fourth embodiment.

FIGS. 13(a) to 13(f) are cross-sectional views illustrating some of the steps from the light-emitting element layer forming step through the sealing film forming step according to the fourth embodiment in order of the steps.

FIG. 14 is a cross-sectional view illustrating a configuration of a display region of a display device according to a fifth embodiment.

FIG. 15 is a flowchart illustrating an example of a sealing film forming step according to the fifth embodiment.

FIGS. 16(a) to 16(e) are cross-sectional views illustrating some of the steps from the light-emitting element layer forming step through the sealing film forming step according to the fifth embodiment in order of the steps.

### DESCRIPTION OF EMBODIMENTS

### First Embodiment

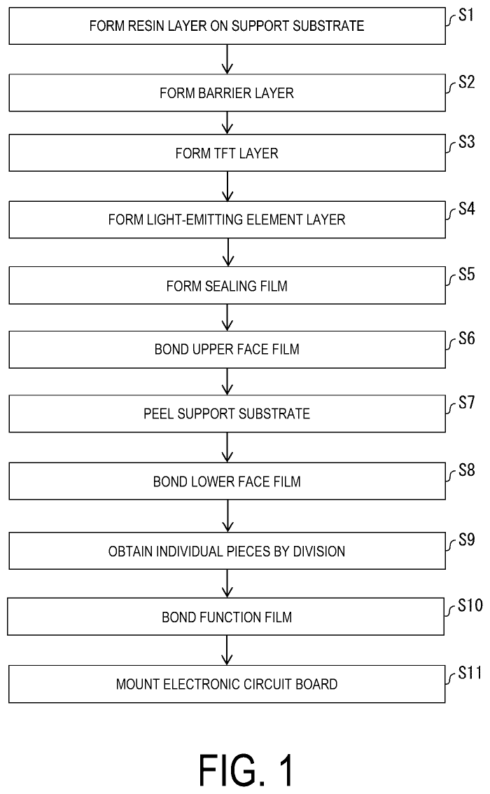

Hereinafter, a manufacturing method of a display device according to an embodiment of the present invention will be described in detail with reference to FIGS. 1 to 16. Note that, hereinafter, “the same layer” means that the layer is formed in the same step (film formation step), “a lower layer” means that the layer is formed in an earlier step than the step in which the layer to compare is formed, and “an upper layer” means that the layer is formed in a later step than the step in which the layer to compare is formed.

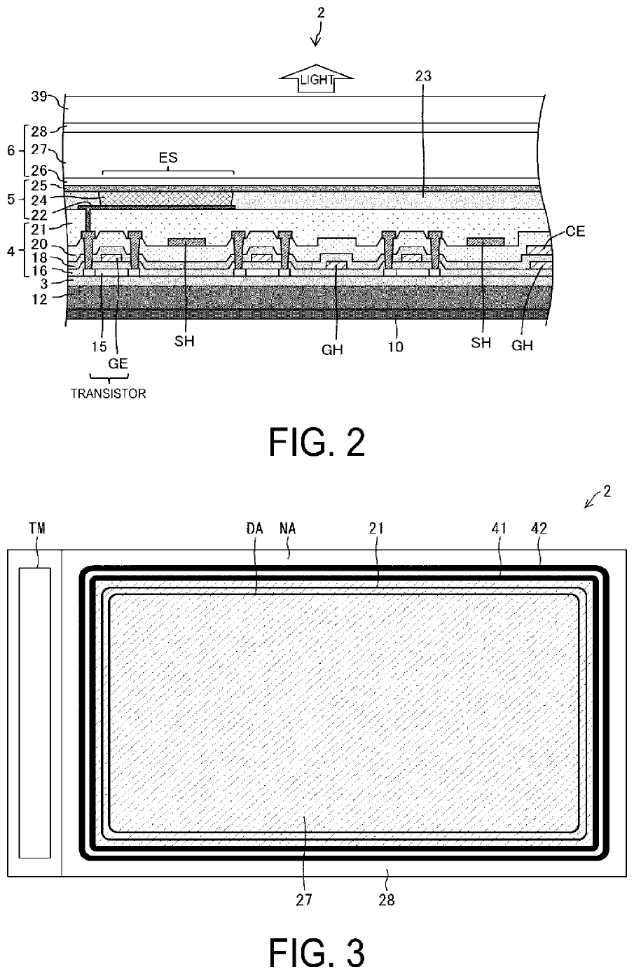

Configuration and manufacturing method of display device FIG. 1 is a flowchart illustrating an example of a manufacturing method of a display device according to a first embodiment of the present embodiment. FIG. 2 is a cross-sectional view illustrating a configuration of a display region of the display device according to the present embodiment. FIG. 3 is a plan view illustrating a general configuration of the display device according to the present embodiment.

In a case that a flexible display device is manufactured, as illustrated in FIGS. 1 and 2, first, a resin layer 12 is formed on a transparent support substrate (a mother glass, for example) (S1). Then, a barrier layer 3 is formed (S2). Then, a TFT layer 4 is formed (S3). Then, a top-emitting type light-emitting element layer 5 is formed (S4). Then, a sealing film 6 is formed (S5). Then, an upper face film is bonded on the sealing film 6 (S6).

Then, the support substrate is peeled from the resin layer 12 by irradiation with laser light or the like (S7). Then, a lower face film 10 is bonded to the lower face of the resin layer 12 (S8). Then, a layered body including the lower face film 10, the resin layer 12, the barrier layer 3, the TFT layer 4, the light-emitting element layer 5, and the sealing film 6 is partitioned into a plurality of individual pieces (S9). Then, an upper face film 39 is bonded to the obtained individual pieces (S10). Then, an electronic circuit board (for example, an IC chip and an FPC) is mounted to a portion (terminal portion TM, see FIG. 3) of a region (non-display region NA, a framework) outside a display region DA (see FIG. 3) in which a plurality of subpixels are formed (S11). Note that S1 to S11 are performed by a display device manufacturing apparatus (including a film formation apparatus that performs the steps S1 to S5).

Examples of a material for the resin layer 12 include polyimide. The portion of the resin layer 12 can be replaced with a bilayer resin film (for example, a polyimide film) and an inorganic insulating film sandwiched therebetween.

The barrier layer 3 is a layer that prevents a foreign matter such as water and oxygen from entering the TFT layer 4 or the light-emitting element layer 5, and can be formed of a silicon oxide film, a silicon nitride film, or a silicon oxynitride film, or by a layered film of these films, formed by chemical vapor deposition (CVD).

The TFT layer 4 includes a semiconductor film 15, an inorganic insulating film 16 (gate insulating film) in an upper layer overlying the semiconductor film 15, gate electrodes GE and gate wiring lines GH in an upper layer overlying the inorganic insulating film 16, an inorganic insulating film 18 in an upper layer overlying the gate electrodes GE and the gate wiring lines GH, a capacitance electrode CE in an upper layer overlying the inorganic insulating film 18, an inorganic insulating film 20 in an upper layer than the capacitance wiring line CE, a source wiring line SH in an upper layer overlying the inorganic insulating film 20, and an interlayer insulating film 21 in an upper layer overlying the source wiring line SH.

The semiconductor film 15 is formed of, for example, low-temperature polysilicon (LTPS) or an oxide semiconductor (for example, an In—Ga—Zn—O-based semiconductor), and a transistor (TFT) is formed of the semiconductor film 15 and the gate electrode GE. FIG. 2 illustrates the transistor in a top gate structure, but the transistor may have a bottom gate structure.

The gate electrodes GE, the gate wiring line GH, the capacitance electrode CE, and the source wiring line SH each is formed of a metal single layer film or a layered film of metal including at least one of, for example, aluminum (Al), tungsten (W), molybdenum (Mo), tantalum (Ta), chromium (Cr), titanium (Ti), and copper (Cu). The TFT layer 4 in FIG. 2 includes a single semiconductor layer and a three-layer metal layer.

Each of the inorganic insulating films 16, 18, and 20 can be formed of, for example, a silicon oxide (SiOx) film or a silicon nitride (SiNx) film, or a layered film of these, formed using CVD. The interlayer insulating film 21 can be formed of, for example, a coatable photosensitive organic material, such as a polyimide, an acrylic, or the like.

The light-emitting element layer 5 includes an anode 22 in an upper layer overlying the interlayer insulating film 21, an anode cover film 23 having insulating properties and covering an edge of the anode 22, an electroluminescence (EL) layer 24 in an upper layer overlying the anode cover film 23, and a cathode 25 in an upper layer overlying the EL layer 24. The light-emitting element layer 5 may include a capping layer such as an organic capping layer or an inorganic capping layer in an upper layer overlying the cathode 25. The anode cover film 23 is formed by applying an organic material such as a polyimide or an acrylic resin and then by patterning the organic material by photolithography, for example.

For each subpixel, a light-emitting element ES including the anode 22 shaped like an island, the EL layer 24, and the cathode 25 (for example, an OLED: organic light emitting diode, QLED: quantum dot diode) is formed in the light-emitting element layer 5, and a subpixel circuit controlling the light-emitting element ES is formed in the TFT layer 4.

For example, the EL layers 24 are formed by layering a hole injection layer, a hole transport layer, a light-emitting layer, an electron transport layer, and an electron injection layer in this order, from the lower layer side. The light-emitting layer is formed into an island shape at an opening (for each subpixel) in the anode cover film 23 by vapor deposition or an ink-jet method. Other layers are formed in an island shape or a solid-like shape (common layer). A configuration is also possible in which one or more layers are not formed, out of the hole injection layer, the hole transport layer, the electron transport layer, and the electron injection layer.

In a case that the light-emitting layer of the OLED is formed by vapor deposition, a fine metal mask (FMM) is used. The FMM is a sheet including a large number of openings (and made of, for example, an invar material), and an island shaped light-emitting layer (corresponding to one subpixel) is formed by an organic material passing through one opening.

For the light-emitting layer of a QLED, an island shaped light-emitting layer (corresponding to one subpixel) can be formed by ink-jet coating a solvent with quantum dots diffused into the solvent.

The anode (anode electrode) 22 is formed by layering of Indium Tin Oxide (ITO) and silver (Ag) or alloy containing Ag, for example, and have light reflectivity. The cathode (cathode electrode) 25 can be formed of a transparent conductive material such as a MgAg alloy (extremely thin film), ITO, or IZO (Indium zinc Oxide).

In a case that the light-emitting element layer ES is an OLED, a drive current between the anode 22 and the cathode 25 recombines positive holes and electrons inside the light-emitting layer to generate excitons. During transition of the excitons into a ground state, light is emitted. Since the cathode 25 is transparent and the anode 22 has light reflectivity, the light emitted from the EL layer 24 travels upward and becomes top-emitting.

In a case that the light-emitting element ES is a QLED, a drive current between the anode 22 and the cathode 25 recombines positive holes and electrons inside the light-emitting layer to generate excitons. During transition of the excitons from a conduction band of the quantum dots to a valence band of the quantum dots, light (fluorescence) is emitted.

A light-emitting element (such as an inorganic light emitting diode) other than the OLED or QLED may be formed in the light-emitting element layer 5.

The sealing film 6 is transparent, and includes an inorganic layer 26 covering the cathode 25, an organic layer 27 (an organic sealing layer) in an upper layer overlying the inorganic layer 26, and an inorganic film 28 in an upper layer overlying the organic layer 27 (see FIG. 2). The sealing film 6 covering the light-emitting element layer 5 prevents a foreign matter such as water and oxygen from infiltrating into the light-emitting element layer 5. Note that materials for the sealing film forming step (S5) and the sealing film 6 will be described in detail below.

The inorganic layer 26 and the inorganic layer 28 can be formed of a silicon oxide film, a silicon nitride film, a silicon oxynitride film, or a layered film of these films, formed by CVD, for example. The organic layer 27 is a transparent organic layer having a flattening effect and can be formed of an organic material such as an acrylic resin or PI.

The organic layer 27 can be formed by, for example, ink-jet coating.

As illustrated in FIG. 3, the non-display region NA may be provided with a bank 41 shaped like a frame to hold back the ink used for ink-jet coating (liquid organic material) and a bank 42 shaped like a frame to surround the bank 41, the bank 41 and the bank 42 surrounding the interlayer insulating film 21.

The bank 41 holds back the ink used to form the organic layer 27, defining an edge of the organic layer 27. The bank 42 holds back ink that flows over the bank 41 in a case that the bank 41 fails to hold back the ink.

The inside of the bank 41 is covered with the organic layer 27, and the edge of the organic layer 27 overlaps with the bank 41. Thus, the region surrounded by the bank 41 is used as a formation region of the organic layer 27.

The bank 41 may be formed using the same material as that of the anode cover film 23 simultaneously with formation of the anode cover film 23. Additionally, the bank 42 has a two-layer structure with a lower layer and an upper layer, for example. The lower layer can be formed using the same material as that of the interlayer insulating film 21 simultaneously with formation of the interlayer insulating film 21. The upper layer may be formed using the same material as that of the anode cover film 23 simultaneously with formation of the anode cover film 23.

The lower face film 10 is a film bonded on a lower face of the resin layer 12 after the support substrate is peeled off, to provide a display device with excellent flexibility, and is, for example, a PET film. The upper face film 39 has at least one of, for example, an optical compensation function, a touch sensor function, and a protection function.

The flexible display device has been described. However, in a case that a non-flexible display device is manufactured, generally, formation of a resin layer or replacement of a base material and the like are unnecessary, and thus, for example, layering steps from S2 to S5 are performed on the glass substrate, and the process proceeds to step S9.

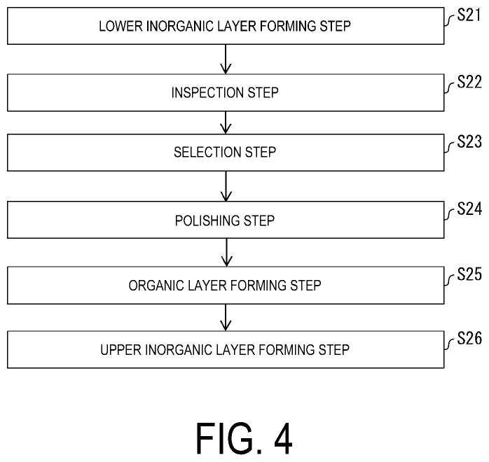

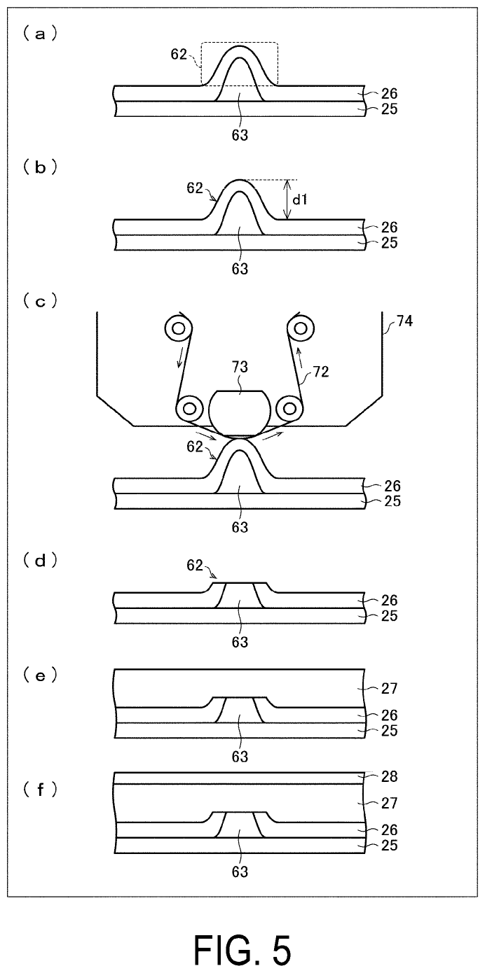

FIG. 4 is a flowchart of an example of the sealing film forming step according to the present embodiment. (a) to (f) of FIG. 5 are cross-sectional views illustrating the sealing film forming step according to the present embodiment in order of relevant steps.

As illustrated in FIG. 4, the sealing film forming step (S5) according to the present embodiment includes a lower inorganic layer forming step (S21), an inspection step (S22), a selection step (S23), a polishing step (S24), an organic layer forming step (S25), and an upper inorganic layer forming step (S26).

In the lower inorganic layer forming step (S21), as illustrated in (a) of FIG. 5, an inorganic layer 26 (second inorganic sealing layer and sealing layer), that is a lower inorganic layer, is formed. At this time, even in a case that a foreign matter 63 is adhered onto the light-emitting element layer 5 (for example, the cathode 25), without removing the foreign matter 63, the inorganic layer 26 is formed extending from the display region DA to the non-display region NA to cover the foreign matter 63. As described above, for example, a CVD method is used as a method for forming the inorganic layer 26.

To be provided to the inspection step (S22), the substrate on which the inorganic layer 26 is formed in the lower inorganic layer forming step (S21) is suitably transported, under an atmosphere of inert gas such as nitrogen, out from a film formation chamber used to form the inorganic layer 26. The inspection step (S22), the selection step (S23), and the polishing step (S24) are all performed under an atmosphere of inert gas such as nitrogen, and movement of the substrate between these steps and movement of the substrate after the polishing step (S24) are also performed under an atmosphere of inert gas such as nitrogen. Note that in the present embodiment, the inorganic layer 26 is formed on the surface of the substrate, and thus transport of the substrate from the film formation chamber, and the inspection step (S22) and the selection step (S23) need not necessarily be performed under an atmosphere of inert gas. However, a portion of the inorganic layer 26 is polished in the polishing step (S24), and thus the polishing step (S24) and transport of the substrate after the polishing step (S24) need to be performed under an atmosphere of inert gas such as nitrogen.

In the inspection step (S22), after the lower inorganic layer forming step (S21), the positions and heights of protrusions 62 present in a formation region of the organic layer 27 are checked, each of the protrusions including at least a foreign matter 63 and protruding upward from a plane at the periphery of the foreign matter 63. Here, inspection refers to acquiring position information and height information regarding the protrusion 62.

In the present embodiment, as described above, the foreign matter 63 is covered by the inorganic layer 26. Thus, in the present embodiment, the plane at the periphery of the foreign matter 63 means the surface of a portion of the inorganic layer 26 in which no foreign matter is present at the periphery of the foreign matter 63 (that is, the plane formed of the inorganic layer 26). In addition, in the present embodiment, the protrusion 62 refers to a portion in which the foreign matter 63 and the inorganic layer 26 covering the foreign matter protrude from the plane formed of the inorganic layer 26 at the periphery of the foreign matter 63, as illustrated in the frame box in (a) of FIG. 5. Additionally, the height of the protrusion 62 refers to a height from the plane measured using the plane as a reference plane.

In the present embodiment, the protrusion 62 includes the foreign matter 63 and the inorganic layer 26 covering the foreign matter 63. As illustrated in (b) of FIG. 5, the height of the protrusion 62 protruding upward from the plane means the height d1 of the protrusion 62 protruding from the plane formed of the inorganic layer 26 at the periphery of the foreign matter 63.

In the inspection step (S22), a method for inspecting the position and height d1 of the protrusion 62 is not particularly limited. Examples of the methods include a method for inspection using an automated optical inspection (AOI) device including a charge coupled device (CCD) camera.

In the selection step (S23), the protrusion 62 is selected having the height d1 of the protrusion 62, inspected in the inspection step (S22) and illustrated in (b) of FIG. 5, equal to or greater than a threshold value.

The threshold value is set to a value that is equal to or less than the thickness of the organic sealing layer (first flattened layer) resulting from the polishing step (S24).

Thus, in the present embodiment, a value equal to or less than the thickness of the organic layer 27 is set as the threshold value. In this case, the protrusion 62 whose height d1 is equal to or greater than the thickness of the organic layer 27 is selected as an object to be polished in the polishing step (S24) described below.

By setting the threshold value to a value equal to or less than the thickness of the organic layer 27, the height d1 of the protrusion 62 can be reliably set less than the thickness of the organic layer 27.

In the polishing step (S24), as illustrated in (c) and (d) of FIG. 5, a portion of the protrusion 62 selected in the selection step (S23) is polished to make the height of the protrusion 62 less than the threshold value, in other words, the height is less than the thickness of the organic sealing layer (first flattened layer) resulting from the polishing step (S24). Accordingly, in the present embodiment, a portion of the protrusion 62 is polished to make the height d1 of the protrusion 62 less than the thickness of the organic layer 27. The protrusion 62 having a height less than the threshold value (in other words, the height that can be sealed by the organic layer 27) is subjected to the steps subsequent to the organic layer forming step (S25) without polishing.

In the present step, as illustrated in (c) of FIG. 5, the polishing of the foreign matter 63 can be performed using, for example, a polishing apparatus 74 including a polishing member (polishing tape 72) shaped like a tape. Specifically, the polishing tape 72 of the polishing apparatus 74, sandwiched between a polishing head 73 and the surface of the protrusion 62, moves in the direction of an arrow, and thus the surface of the protrusion 62 in contact with a surface of the polishing tape 72 can be polished.

In addition, at polishing and after polishing, a step such as air blowing or suction may be performed in order to remove debris (not illustrated) generated from the foreign matter 63 by polishing.

The amount of polishing may be an amount at which the height d1 of the protrusion 62 is less than the thickness of the organic layer 27, but the height d1 of the protrusion 62 after polishing is preferably set to be no greater than half the thickness of the organic layer 27. By setting the amount of polishing in this manner, in a case that the foreign matter 63 is present in the display region DA illustrated in FIG. 3 (on the cathode 25, for example, as illustrated in (a) to (f of FIG. 5), the surface of the organic layer 27 in the display region DA can be reliably flattened in the organic layer forming step (S25) described below. As an example of the amount of polishing, in the case where the organic layer 27 having a thickness of 10 μm is formed in the organic layer forming step (S25), the protrusion 62 is polished until the height of the foreign matter 63 is 10 μm or less, and preferably 5 μm or less.

In the organic layer forming step (S25), as illustrated in (e) of FIG. 5, the organic layer 27 is formed to cover the foreign matter 63 that has been polished in the polishing step (S24). As described above in the polishing step (S24), the height of the polished foreign matter 63 is less than the thickness of the organic layer 27. Thus, even in a case that, in the present step, the organic layer 27 is formed on the foreign matter 63, with the foreign matter 63 remaining in the formation region of the organic layer 27, the organic layer 27 can be formed with the foreign matter 63 prevented from protruding from the surface of the organic layer 27.

As described above, the organic layer 27 is formed, for example, by applying, by ink-jet coating or the like, ink into a region enclosed by a bank 41, and curing the ink by UV curing or the like. The ink can be made of a coatable organic material such as an acrylic resin.

In the upper inorganic layer forming step (S26), as illustrated in (f) of FIG. 5, an inorganic layer 28 (first inorganic sealing layer), that is an upper inorganic layer, is formed on the organic layer 27, as is the case with the inorganic layer 26.

The inorganic layer 26 and the inorganic layer 28 have a moisture-proof function to prevent penetration of moisture, and function as barrier layers to prevent degradation of the light-emitting element ES caused by moisture or oxygen. The organic layer 27 relieves stress on the inorganic layers 26 and 28 having high film stress, covers steps and the foreign matter 63 on the surface of the light-emitting element layer 5 for flattening, fills up pinholes, or suppresses occurrence of cracks or film peeling at the time of layering the inorganic layer 28.

The thickness of each of the inorganic layers 26 and 28 is, for example, 500 to 1500 nm. The thickness of the organic layer 27 is, for example, 5 μm or more and 15 μm or less.

According to the present embodiment, as described above, after the inorganic layer 26 is formed to cover the foreign matters 63 present in the formation region of the organic layer 27, the positions and heights of the foreign matters 63 covered by the inorganic layer 26 (in other words, the protrusions 62 including the foreign matters 63) are inspected, and the protrusion 62 having a height at which the protrusion fails to be covered by the organic layer 27 is selected and polished. At this time, in the present embodiment, only a portion of the protrusion 62 is polished down to a height at which the protrusion can be covered by the organic layer 27, and not the entire protrusion 62 is polished. Accordingly, poor sealing can be suppressed before the inorganic layer 28 is formed, and an increase in the number of foreign matters 63 and possible defects such as cracks in the inorganic layer 26 are prevented. Thus, the display device 2 having high reliability can be manufactured.

### Second Embodiment

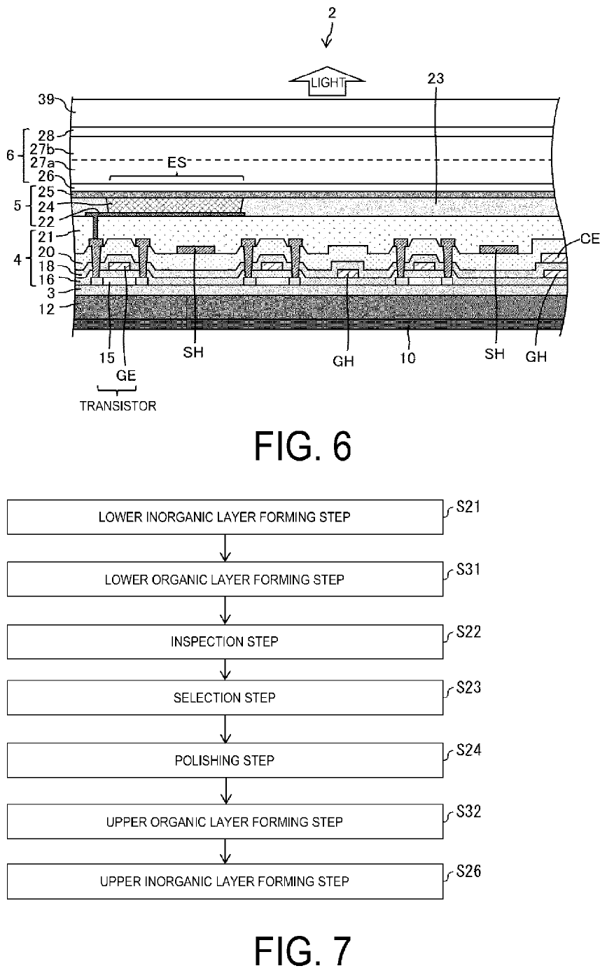

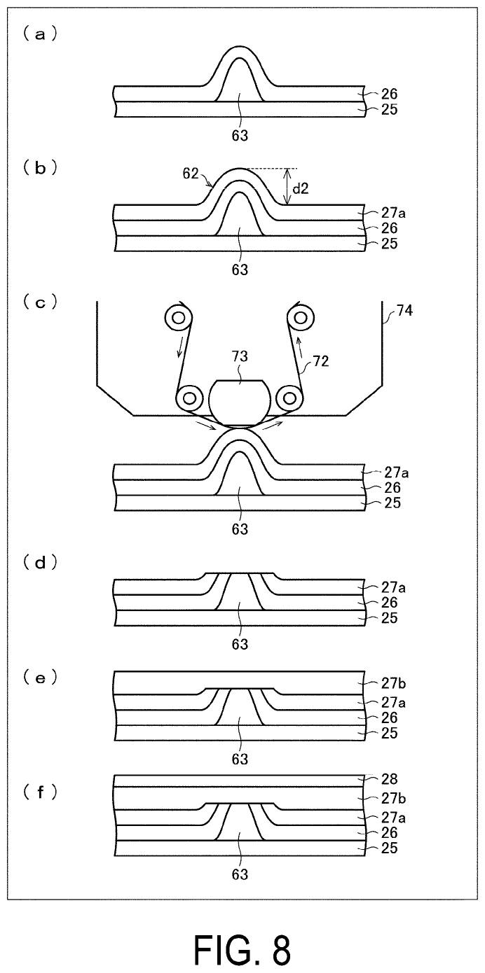

The display device 2 according to the present embodiment and a manufacturing method of the display device 2 according to the present embodiment will be described in detail with reference to FIGS. 7 and 8. FIG. 6 is a cross-sectional view illustrating a configuration of a display region of the display device according to the present embodiment. FIG. 7 is a flowchart of an example of a sealing film forming step according to the present embodiment. (a) to (f) of FIG. 8 are cross-sectional views illustrating the sealing film forming step according to the present embodiment in order of the relevant steps. A description follows regarding differences from the first embodiment.

As illustrated in FIG. 6, the display device 2 according to the present embodiment includes the organic layer 27 including a lower organic layer 27a (second flattened layer and sealing layer), and an upper organic layer 27b (first flattened layer and organic sealing layer) formed on the lower organic layer 27a. The total thickness of the lower organic layer 27a and the upper organic layer 27b is set as is the case with the thickness of the organic layer 27 described above. The lower organic layer 27a and the upper organic layer 27b have approximately the same thickness, which is set to, for example, half the thickness of the above-described organic layer 27.

As illustrated in FIG. 7, the sealing film forming step (S5) according to the present embodiment includes the lower inorganic layer forming step (S21), the lower organic layer forming step (S31), the inspection step (S22), the selection step (S23), the polishing step (S24), the upper organic layer forming step (S32), and the upper inorganic layer forming step (S26) in this order.

In the present embodiment, as illustrated in FIG. 7 and (a) of FIG. 8, after the lower inorganic layer forming step (S21) in the first embodiment, the lower organic layer 27a having a thickness that is, for example, half the thickness of the organic layer 27 is formed on the inorganic layer 26 formed in the lower inorganic layer forming step (S21), as illustrated in (b) of FIG. 8 (S31). Note that the lower organic layer 27a is formed, for example, by applying, by ink-jet coating or the like, ink into a region enclosed by the bank 41 and curing the ink by UV curing or the like as is the case with the organic layer 27 illustrated in FIG. 2.

In the present embodiment, after the lower organic layer forming step (S31), the inspection step (S22), the selection step (S23), and the polishing step (S24) are performed. Thus, in the inspection step (S22), after the lower organic layer forming step (S31), the positions and heights of the protrusions 62 present in the formation region of the organic layer 27 are inspected, each of the protrusions 62 including at least the foreign matter 63 and protruding upward from the plane at the periphery of the foreign matter 63.

In the present embodiment, the foreign matter 63 is covered by the inorganic layer 26 and the lower organic layer 27a. Thus, in the present embodiment, as illustrated in (b) of FIG. 8, the protrusion 62 indicates a portion in which the foreign matter 63 and the inorganic layer 26 and the lower organic layer 27a covering the foreign matter 63 protrude from the plane formed of the lower organic layer 27a at the periphery of the foreign matter 63. In the present embodiment, the protrusion 62 includes the foreign matter 63, and the inorganic layer 26 and the lower organic layer 27a covering the foreign matter 63. In the present embodiment, in the inspection step (S22), as the position and height of the protrusion 62 including at least the foreign matter 63 and protruding upward from the plane at the periphery of the foreign matter 63, the position and height d2 of the protrusion 62 protruding upward from the surface of a portion of the lower organic layer 27a that is located at the periphery of the foreign matter 63 and in which no foreign matter is present (in other words, the plane formed of the lower organic layer 27a).

Then, in the selection step (S23), the protrusion 62 is selected having the height d2, illustrated in (b) of FIG. 8 and inspected in the inspection step (S22), equal to or greater than the threshold value.

In this case, as the threshold value, a value is set that is equal to or less than the thickness of the organic sealing layer (first flattened layer) resulting from the polishing step (S24). Accordingly, in the present embodiment, the organic sealing layer is the upper organic layer 27b, and as the threshold value, a value is set that is equal to or less than the thickness of the upper organic layer 27b. Thus, in the present embodiment, the protrusion 62 the height d2 of which is equal to or greater than the thickness of the upper organic layer 27b is selected to be polished in the polishing step (S24). By setting the threshold value to a value equal to or less than the thickness of the upper organic layer 27b, the height d2 of the protrusion 62 can be reliably set less than the thickness of the upper organic layer 27b.

In the polishing step (S24), as illustrated in (c) and (d) of FIG. 8, a portion of the protrusion 62 selected in the selection step (S23) is polished to make the height of the protrusion 62 less than the threshold level, that is, less than the thickness of the organic sealing layer (first flattened layer) resulting from the polishing step (S24). Accordingly, in the present embodiment, a portion of the protrusion 62 is polished to make the height d2 of the protrusion 62 less than the thickness of the upper organic layer 27b. As an example of the amount of polishing, in a case that each of the lower organic layer 27a and the upper organic layer 27b has a thickness of 5 μm, then in the present step, the protrusion 62 is polished until the height of the foreign matter 63 is 5 μm or less.

In the upper organic layer forming step (S32), as illustrated in (e) of FIG. 8, the upper organic layer 27b is formed to cover the protrusion 62 polished in the polishing step (S24). The upper organic layer 27b is formed, for example, by applying, by ink-jet coating or the like, the ink into the region enclosed by the bank 41, and curing the ink by UV curing or the like, as is the case with the lower organic layer 27a.

As described above in the polishing step (S24), the height of the polished protrusion 62 is less than the thickness of the upper organic layer 27b. Thus, even in a case that, in the present step, the upper organic layer 27b is formed on the protrusion 62 remaining in the formation regions of the lower organic layer 27a and the upper organic layer 27b, the upper organic layer 27b can be formed to prevent the protrusion 62 including the foreign matter 63 from protruding from the surface of the upper organic layer 27b.

In the upper inorganic layer forming step (S26), as illustrated in (f) of FIG. 8, the inorganic layer 28 is formed on the upper organic layer 27b as is the case with the first embodiment.

According to the present embodiment, as described above, after the inorganic layer 26 and the lower organic layer 27a are formed to cover the foreign matters 63 present in the formation region of the organic layer 27 (that is, the formation regions of the lower organic layer 27a and the upper organic layer 27b), the positions and heights of foreign matters 63 covered by the inorganic layer 26 and the lower organic layer 27a (in other words, the protrusions 62 including the foreign matters 63) are inspected, and the protrusion 62 having a height at which the protrusion fails to be covered by the upper organic layer 27b is selected, and the selected protrusion 62 is polished. At this time, in the present embodiment, only a portion of the protrusion 62 is polished down to a height at which the protrusion can be covered by the upper organic layer 27b, and not the entire protrusion 62 is polished. Accordingly, poor sealing can be suppressed before the inorganic layer 28 is formed, and an increase in the number of foreign matters 63 and possible defects such as cracks in the inorganic layer 26 are prevented. Thus, the display device 2 having high reliability can be manufactured.

### Third Embodiment

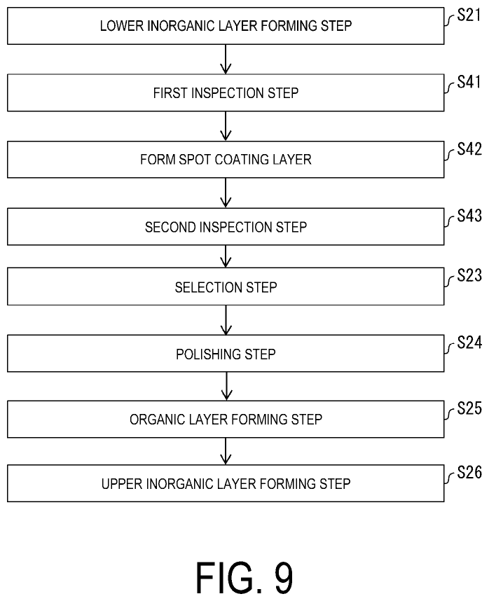

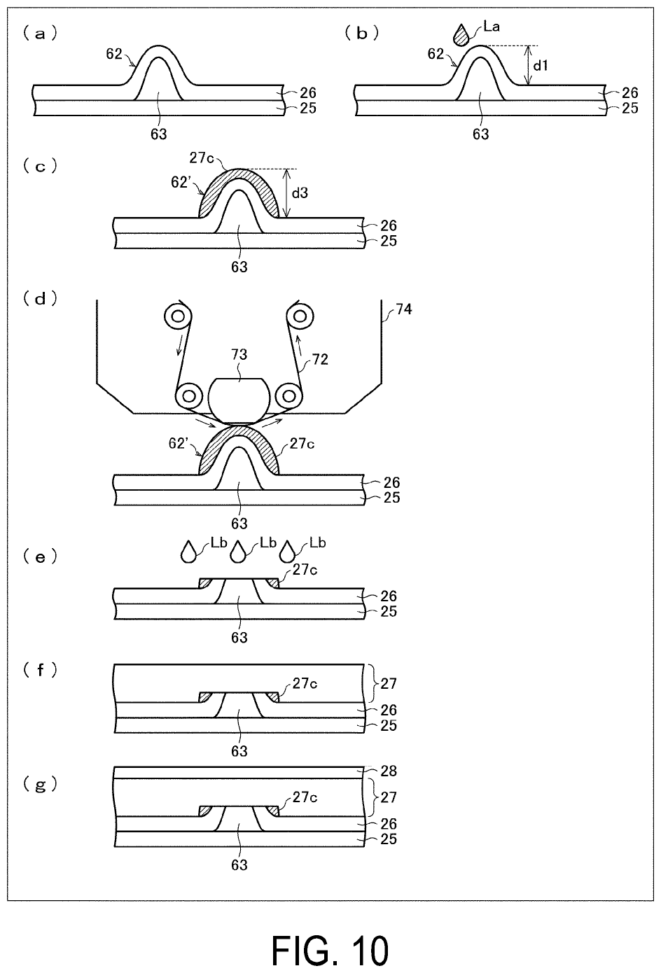

A method of manufacturing the display device 2 according to the present embodiment will be described in detail below with reference to FIG. 9 and (a) to (g) of FIG. 10. FIG. 9 is a flowchart illustrating an example of a sealing film forming step according to the present embodiment. (a) to (g) of FIG. 10 are cross-sectional views of a part of the sealing film forming step according to the present embodiment in order of relevant steps. A description follows regarding differences from the first embodiment.

As illustrated in FIG. 9, the sealing film forming step (S5) according to the present embodiment includes, for example, a first inspection step (S41), a spot coating layer forming step (S42), a second inspection step (S43), a selection step (S23), a polishing step (S24), an organic layer forming step (S25), and an upper inorganic layer forming step (S26), for example, in this order.

In the present embodiment, as illustrated in FIG. 9 and (a) of FIG. 10, after the lower inorganic layer forming step (S21) in the first embodiment, the first inspection step (S41) is performed as in the inspection step (S22) according to the first embodiment, by using, for example, AOI or the like, to locate the protrusion 62. Thus, the protrusion 62 located in the first inspection step (S41) indicates a portion in which the foreign matter 63 and the inorganic layer 26 covering the foreign matter 63 protrude from the plane formed of the inorganic layer 26 at the periphery of the foreign matter 63, as in the first embodiment.

Then, as illustrated in (b) of FIG. 10, ink La (liquid organic material) is locally applied by an ink-jet method and to cover the surface of the protrusion 62 located in the first inspection step (S41) (organic material application step). Subsequently, the ink La covering the surface of the protrusion 62 is cured by UV curing or the like (organic material curing step). Thus, as illustrated in (c) of FIG. 10, a spot coating layer 27c of the ink La is formed.

Examples of the organic material (resin material) contained in the ink La include polyimide, acrylate, polyurea, parylene, and polyamide. Here, each droplet of the ink La contains approximately 10 pL, and the viscosity of the ink La is approximately 0.01 Pa-s. The ejection frequency of the ink La is from approximately several kHz to approximately several tens of kHz, for example. The ejection voltage of the ink La is from approximately 7 V to approximately 15 V, for example. The ejection velocity of the ink La is approximately from 8 m/s to approximately 10 m/s. Note that before the ink La is ejected, meniscus of the ink La inside the nozzle may be vibrated to facilitate ejection of the first shot. Additionally, the viscosity of the ink La (e.g., 0.02 Pa-s) may be set higher than the viscosity of ink Lb described below (e.g., 0.01 Pa-s) to reliably place the ink La on the foreign matter 63. In addition, the ejection velocity of the ink La (e.g., 10 m/s) may be set higher than the ejection velocity of the ink Lb described below (e.g., 8 m/s) to reliably place the ink La on the foreign matter 63. The ink La and the ink Lb are made of the same organic material (a resin material, but the inks La and Lb may have different viscosities as described above), but may be made of different organic materials (different resin materials).

Subsequently, the second inspection step (S43) is performed similarly to the first inspection step (S41) using, for example, AOI or the like. In the second inspection step (S43), the foreign matter 63 is covered by the inorganic layer 26 and the spot coating layer 27c. In the second inspection step (S43), after the spot coating layer forming step (S42), the positions and heights of protrusions 62′ present in the formation region of the organic layer 27 are inspected, each of the protrusions 62′ including at least the foreign matter 63 and protruding upward from the plane at the periphery of the foreign matter 63. Here, as illustrated in (c) of FIG. 10, the protrusion 62′ indicates a portion in which the foreign matter 63 and the inorganic layer 26 and the spot coating layer 27c covering the foreign matter 63 protrude from the plane formed of the inorganic layer 26 at the periphery of the foreign matter 63. In other words, the protrusion 62′ includes the foreign matter 63 and the spot coating layer 27c covering the foreign matter 63. In the second inspection step (S43), the positions and heights d3 of the protrusions 62′ protruding upward from the surface (that is, a plane formed of the inorganic layer 26) of a portion of the inorganic layer 26 that is located at the periphery of the foreign matter 63 and in which no foreign matter 63 is present.

Then, in the selection step (S23), the protrusions 62′ is selected having the height d3 inspected in the second inspection step (S23) and illustrated in (b) of FIG. 10, equal to or greater than the threshold value (first threshold). The threshold value is set to a value that is equal to or less than the thickness of the organic layer 27. Thus, in the present embodiment, the protrusion 62′ the height d3 of which is equal to or greater than the thickness of the organic layer 27 selected to be polished in the polishing step (S24). By setting the threshold value to a value equal to or less than the thickness of the organic layer 27, the height d3 of the protrusion 62′ can be reliably set to be less than the thickness of the organic layer 27.

In a polishing step (S24), as illustrated in (d) of FIG. 10, a portion of the protrusion 62′ selected in the selection step (S23) is polished to make the height of the protrusion 62′ less than the threshold value (first threshold value), that is, less than the thickness of the organic layer 27.

In the organic layer forming step (S25), as illustrated in (e) of FIG. 10, the ink Lb is applied by ink-jet coating or the like into the region enclosed by the bank 41 to cover the protrusion 62′ that is polished in the polishing step (S24). Subsequently, the ink Lb is cured by UV curing or the like to form the organic layer 27.

As described in the polishing step (S24) described above, the height of the polished protrusion 62′ is less than the thickness of the organic layer 27. Thus, even in a case that, in the present step, the organic layer 27 is formed on the protrusion 62′ remaining in the formation region of the organic layer 27, the organic layer 27 can be formed to prevent the protrusion 62′ from protruding from the plane of the organic layer 27.

In the upper inorganic layer forming step (S26), as illustrated in (g) of FIG. 10, the inorganic layer 28 is formed on the organic layer 27 as in the first embodiment.

According to the present embodiment, the same effects as those of the first embodiment can be produced, and as described above, before the polishing step (S24), the ink La is locally applied to cover the protrusion 62 and form the spot coating layer 27c. This allows mitigation of damage (stress relief) to the underlayer of the polished protrusion 62′ in the polishing step (S24).

Note that in the organic material coating step, the surfaces of all of the protrusions 62 may be covered by the ink La regardless of the height d1 of each of the protrusions 62 inspected in the first inspection step S27 and that, after the first inspection step (S27), a selection step similar to the selection step (S23) may be performed, and the surface of the protrusion 62 having a height equal to or greater than the threshold value (second threshold) may be covered by the ink La. Here, the second threshold value may be a value less than the first threshold value or may be the same value as the first threshold.

In addition, in the case described above in the present embodiment as an example, the selection step (S23) is performed after the second inspection step (S43). However, in a case that the selection step is performed after the first inspection step (S27), then in the polishing step (S24), for example, the protrusion 62′ is polished in consideration of the height of the spot coating layer 27c resulting from the selection step, thus allowing omission of the second inspection step (S43) and the selection step following the second inspection step (S43). Thus, the selection step (S23) may be performed after the first inspection step (S41) and before the spot coating layer forming step (S42).

In addition, in the case described above in the present embodiment as an example, as illustrated in FIG. 9 and (a) to (g) of FIG. 10, the spot coating layer forming step (S42) is performed after the lower inorganic layer forming step (S21) and before the organic layer forming step (S25). However, it is sufficient to perform, before the polishing step (S24), the first inspection step (S41) of locating the foreign matter 63 on which the spot coating layer 27c is formed and the spot coating layer forming step (S42). Thus, the first inspection step (S41) and the spot coating layer forming step (S42) may, for example, be performed before the lower inorganic layer forming step polishing step (S24) or after the lower organic layer forming step (S31) of the second embodiment.

### Fourth Embodiment

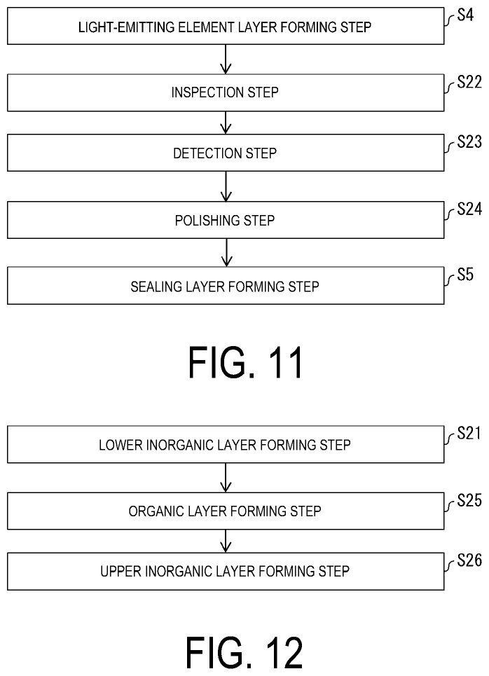

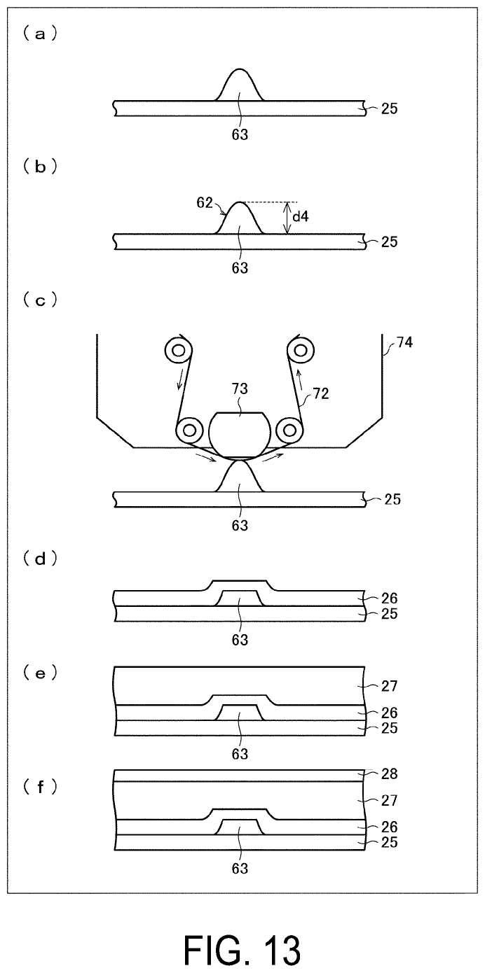

The manufacturing method of the display device 2 according to the present embodiment will be described in detail below with reference to FIG. 11, FIG. 12, and (a) to (f) of FIG. 13. FIG. 11 is a flowchart illustrating an example of steps from a light-emitting element layer forming step to a sealing film forming step according to the present embodiment. FIG. 12 is a flowchart illustrating an example of the sealing film forming step according to the present embodiment. (a) to (f) of FIG. 13 are cross-sectional views illustrating some of the steps from the light-emitting element layer forming step to the sealing film forming step according to the present embodiment in order of the steps. Note that, in the present embodiment, another example of the manufacturing method of the display device 2 illustrated in FIG. 2 according to the first embodiment will be described. A description follows regarding differences from the first embodiment.

In the present embodiment, as illustrated in FIG. 11, after formation of the light-emitting element layer 5 in S4 and before formation of the sealing film 6 in S5, the inspection step (S22), the detection step (S23), and the polishing step (S24) are performed in this order. As illustrated in FIG. 12, the step of forming the sealing film 6 in S5 includes a lower inorganic layer forming step (S21), an organic layer forming step (S25), and an upper inorganic layer forming step (S26) in this order.

In the present embodiment, before the sealing film 6 is formed, the substrate on which the light-emitting element layer 5 is formed is transported out from the film forming chamber in order to be subjected to the inspection step (S22). Thus, with a capping layer (not illustrated) formed in an upper layer overlying the cathode 25, the substrate is transported out from a film formation chamber used to form the inorganic layer 26 under an atmosphere of inert gas such as nitrogen. In addition, the inspection step (S22), the selection step (S23), and the polishing step (S24) are all performed in an inert gas atmosphere such as nitrogen, and the movement of the substrate between the steps and the movement of the substrate after the polishing step (S24) is also performed under an inert gas atmosphere such as nitrogen.

In the present embodiment, after the light-emitting element layer forming step (S4), the inspection step (S22), the selection step (S23), and the polishing step (S24) are performed. Thus, in the inspection step (S22), after the light-emitting element layer forming step (S4), the positions and heights of the protrusions 62 present in the formation region of the organic layer 27 are inspected, each of the protrusions 62 including at least the foreign matter 63 and protruding upward from the plane at the periphery of the foreign matter 63.

Accordingly, in the present embodiment, as illustrated in (a) of FIG. 13, the protrusion 62 indicates a portion in which the foreign matter 63 protrudes from the plane formed of the light-emitting element layer 5 at the periphery of the foreign matter 63 (in other words, the upper surface of the light-emitting element layer 5), and in a case that the foreign matter 63 is adhered onto the upper face of the light-emitting element layer 5, the protrusion 62 is the foreign matter 63 itself.

Note that, in (a) of FIG. 13, illustration of the capping layer is omitted. In the case illustrated in (a) of FIG. 13 as an example, the foreign matter 63 is adhered onto the cathode 25 of the light-emitting element layer 5.

In a case that a portion of the foreign matter 63 is buried in the capping layer, the plane formed of the light-emitting element layer 5 at the periphery of the foreign matter 63 is formed of the capping layer, and the protrusion 62 is a portion protruding upward from the capping layer.

The following describes a case as an example in which, as illustrated in (a) of FIG. 13, the protrusion 62 is the foreign matter 63 itself. In this case, in the inspection step (S22), the position and height d4 of the foreign matter 63 adhered to the upper face of the light-emitting element layer 5 are inspected as the position and height of the protrusion 62, as described above.

Then, in the selection step (S23), the foreign matter 63 is selected having the height d4 of the foreign matter 63, illustrated in (b) of FIG. 13 and inspected in the inspection step (S22), equal to or greater than the threshold value.

In the polishing step (S24), as illustrated in (c) of FIG. 13, a portion of the foreign matter 63 selected in the selection step (S23) is polished to make the height of the foreign matter 63 less than the threshold value, that is, less than the thickness of the organic layer 27 resulting from the polishing step (S24).

In the present embodiment, after the polishing step (S24), the sealing film forming step (S5) is performed. Thus, in the present embodiment, after the polishing step (S24), the inorganic layer 26, the organic layer 27, and the inorganic layer 28 are formed in this order as is the case with the first embodiment, as illustrated in (d) to (f) of FIG. 13.

According to the present embodiment, as described above, for example, the positions and heights d4 of the foreign matters 63 present in the formation region of the organic layer 27 are inspected as the positions and heights of the protrusions 62, and the foreign matter 63 having a height at which the foreign matter 63 fails to be covered by the organic layer 27 is selected and polished. At this time, in the present embodiment, only a portion of the foreign matter 63 is polished down to a height at which the foreign matter 63 can be covered by the organic layer 27, and not the entire foreign matter 63 is polished. Accordingly, poor sealing can be suppressed before the inorganic layer 28 is formed, and an increase in the number of foreign matters 63 and possible defects such as cracks in the inorganic layer 26 are prevented. Thus, the display device 2 having high reliability can be manufactured.

### Fifth Embodiment

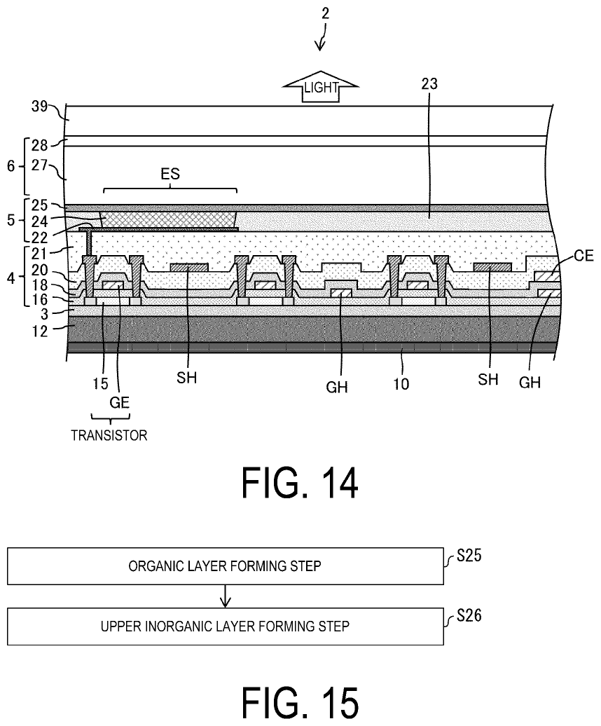

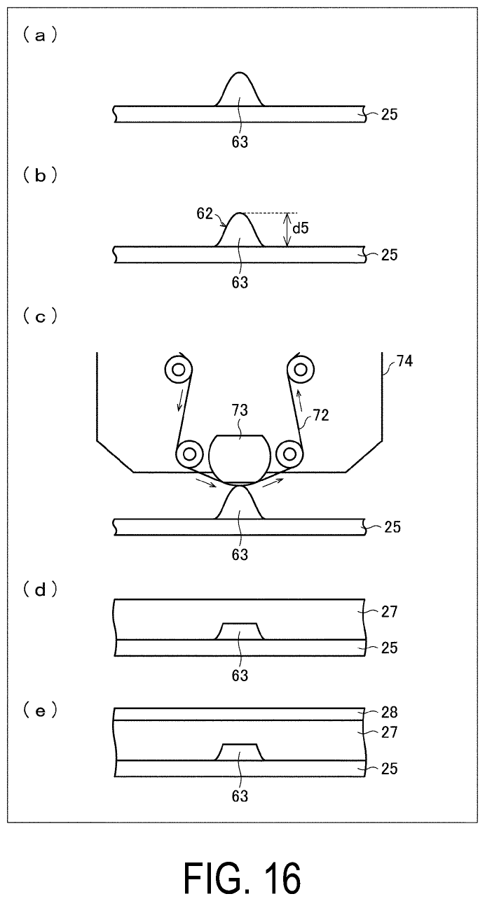

A manufacturing method of the display device 2 according to the present embodiment will be described in detail below with reference to FIG. 11, FIG. 14, FIG. 15, and (a) to (e) of FIG. 16. FIG. 14 is a cross-sectional view illustrating a configuration of a display region of the display device according to the present embodiment. FIG. 15 is a flowchart illustrating an example of a sealing film forming step according to the present embodiment. (a) to (e) of FIG. 16 are cross-sectional views illustrating, some of steps from a light-emitting element layer forming step to a sealing film forming step according to the present embodiment in order of the steps. A description follows regarding differences from the fourth embodiment.

The display device 2 does not necessarily require the inorganic layer 26. Thus, as illustrated in FIG. 14, for example, the display device 2 according to the present embodiment has a configuration in which the sealing film 6 covering the light-emitting element layer 5 includes the organic layer 27 and the inorganic layer 28 layered in that order.

In the present embodiment, as illustrated in FIG. 11, the inspection step (S22), the detection step (S23), and the polishing step (S24) are performed in this order after formation of the light-emitting element layer 5 in S4 and before formation of the sealing film 6 in S5, as in the fourth embodiment. However, in the present embodiment, unlike in the fourth embodiment, the step of forming the sealing film 6 in S5 does not include the lower inorganic layer forming step (S21), and includes the organic layer forming step (S25) and the upper inorganic layer forming step (S26) in this order, as illustrated in FIG. 15.

Steps illustrated in (a) to (c) of FIG. 16 are the same as the steps illustrated in (a) to (c) of FIG. 13. In the present embodiment, after the polishing step (S24), the organic layer 27 and the inorganic layer 28 are formed in this order as in the first embodiment, as illustrated in FIG. 15 and (d) and (e) of FIG. 14.

Accordingly, also in the present embodiment, for example, only a portion of the foreign matter 63 is polished down to a height at which the foreign matter 63 can be covered by the organic layer 27, and not the entire foreign matter 63 is polished, as in the fourth embodiment. Accordingly, poor sealing can be suppressed before the inorganic layer 28 is formed, and an increase in the number of foreign matters 63 and possible defects such as cracks in the inorganic layer 26 are prevented. Thus, the display device 2 having high reliability can be manufactured.

Note that, in the present embodiment, a description has been given of the differences between the present embodiment and the fourth embodiment in the production of the display device 2 illustrated in FIG. 2 but that it goes without saying that the above-described modifications can be made to any of the first to fourth embodiments.

### Supplement

A manufacturing method of a display device according to an aspect of the present invention is a manufacturing method of a display device including a light-emitting element layer including a plurality of light-emitting elements and a sealing film covering the light-emitting element layer, the sealing film including a first flattened layer and a first inorganic sealing layer provided on the first flattened layer, the manufacturing method including a light-emitting element layer forming step of forming the light-emitting element layer, an inspection step of inspecting, after the light-emitting element layer forming step, a position and a height of a protrusion present in a formation region of the first flattened layer, including at least a foreign matter, and protruding upward from a plane at a periphery of the foreign matter, a selection step of selecting the protrusion having a height equal to or greater than a threshold value, a polishing step of polishing a portion of the protrusion having a height equal to or greater than the threshold value to make the height of the protrusion less than a thickness of the first flattened layer, a first flattened layer forming step of forming the first flattened layer to cover the protrusion polished in the polishing step, and a first inorganic sealing layer forming step of forming the first inorganic sealing layer on the first flattened layer.

According to this method, only a portion of the protrusion is polished down to a height at which the protrusion can be covered by the first flattened layer, and not the entire protrusion is polished. Thus, a manufacturing method of a display device can be provided that can suppress poor sealing before forming the first inorganic sealing layer and that can manufacture a highly reliable display device.

In the manufacturing method of a display device described above, the threshold value may be a value equal to or less than the thickness of the first flattened layer.

According to the method described above, the height of the protrusion can be reliably set less than the thickness of the first flattened layer.

In the manufacturing method of a display device, the sealing film may further include a sealing layer provided in a lower layer than the first flattened layer and having a thickness that is less than a height of the foreign matter, the protrusion may be a portion protruding upward from the sealing layer, the manufacturing method may further include a sealing layer forming step of forming the sealing layer before the inspection step, and in the polishing step, a portion of the protrusion protruding upward from the sealing layer may be polished.

According to the method described above, a display device including three layers of a sealing layer, a first flattened layer, and a first inorganic sealing layer can be manufactured without causing defects on the inorganic sealing film.

In the manufacturing method of a display device, the sealing layer may be a second inorganic sealing layer.

In the manufacturing method of a display device, the sealing layer may be a second flattened layer.

In the manufacturing method of a display device, the sealing film may further include a second inorganic sealing layer provided in a lower layer than the first flattened layer and having a thickness less than the height of the foreign matter, the manufacturing method may further include, between the polishing step and the first flattened layer forming step, a second inorganic sealing layer forming step of forming the second inorganic sealing layer to cover the protrusion polished in the polishing step, and in the first flattened layer forming step, the first flattened layer may be formed to cover the protrusion polished in the polishing step and the second inorganic sealing layer formed on the protrusion.

The manufacturing method of a display device may further include an organic material applying step of locally applying, before the polishing step, an organic material to cover the protrusion.

In the manufacturing method of a display device, the organic material may include polyimide.

The present invention is not limited to each of the embodiments described above, and various modifications may be made within the scope of the claims. Embodiments obtained by appropriately combining technical approaches disclosed in each of the different embodiments also fall within the technical scope of the present invention. Moreover, novel technical features can be formed by combining the technical approaches disclosed in the embodiments.

### REFERENCE SIGNS LIST

5 Light-emitting element layer
6 Sealing film
26, 28 Inorganic layer
27 Organic layer
27a Lower organic layer
27b Upper organic layer
27c Spot coating layer
62, 62′ Protrusion
63 Foreign matter

1. A manufacturing method of a display device including a light-emitting element layer including a plurality of light-emitting elements and a sealing film covering the light-emitting element layer, the sealing film including a first flattened layer and a first inorganic sealing layer provided on the first flattened layer, the manufacturing method comprising:
forming the light-emitting element layer;
after forming the light-emitting element layer forming, inspecting a position and a height of a protrusion present in a formation region of the first flattened layer, including at least a foreign matter, and protruding upward from a plane at a periphery of the foreign matter;
selecting the protrusion having a height equal to or greater than a threshold value;
polishing a portion of the protrusion having a height equal to or greater than the threshold value to make the height of the protrusion less than a thickness of the first flattened layer;
forming the first flattened layer covering the polished protrusion; and
forming the first inorganic sealing layer on the first flattened layer,
wherein the method further includes, before polishing the portion of the protrusion, locally applying an organic material to cover the protrusion.

2. The manufacturing method of a display device according to claim 1,
wherein the threshold value is a value equal to or less than the thickness of the first flattened layer.

3. The manufacturing method of a display device according to claim 1,
wherein the sealing film further includes a sealing layer provided in a lower layer than the first flattened layer and having a thickness that is less than a height of the foreign matter, the protrusion is a portion protruding upward from the sealing layer,
the manufacturing method further includes forming the sealing layer before inspecting the position and the height of the protrusion, and
in polishing the portion of the protrusion, a portion of the protrusion protruding upward from the sealing layer is polished.

4. The manufacturing method of a display device according to claim 3,
wherein the sealing layer is a second inorganic sealing layer.

5. The manufacturing method of a display device according to claim 3,
wherein the sealing layer is a second flattened layer.

6. The manufacturing method of a display device according to claim 1, wherein the sealing film further includes a second inorganic sealing layer provided in a lower layer than the first flattened layer and having a thickness less than the height of the foreign matter,
the manufacturing method further includes, between polishing the portion of the protrusion and forming the first flattened layer, forming the second inorganic sealing layer covering the polished protrusion, and
in forming the first flattened layer, the first flattened layer is formed to cover the polished protrusion and the second inorganic sealing layer formed on the protrusion.

7. (canceled)

8. The manufacturing method of a display device according to claim 1,
wherein the organic material includes polyimide.
